(19) United States
(12) Patent Application Publication
(10) Pub. No.: US 2019/0260343 A1
(43) Pub. Date: Aug. 22, 2019

(54) LC FILTER

(71) Applicant: Murata Manufacturing Co., Ltd., Nagaokakyo-shi (JP)

(72) Inventor: Noboru SHIOKAWA, Nagaokakyo-shi (JP)

(21) Appl. No.: 16/400,107

(22) Filed: May 1, 2019

Related U.S. Application Data
(63) Continuation of application No. PCT/JP2017/035906, filed on Oct. 3, 2017.

(30) Foreign Application Priority Data
Nov. 18, 2016 (JP) 2016-225254

(51) Int. Cl. H03H 7/075; H01F 17/00; H01F 27/00; H01G 4/40; H03H 7/09; H03H 7/01

(52) U.S. Cl. CPC H03H 7/075; H01F 17/0013; H01F 27/00; H03H 2001/0085; H03H 7/09; H03H 7/1775; H01G 4/40

(57) ABSTRACT

An LC filter includes first and second LC resonators including first and second inductors, respectively. In plan view from a winding axis direction of the first inductor, an air-core portion of the first inductor does not coincide with an air-core portion of the second inductor. The LC filter includes a bypass conductor that connects an intermediate portion of the first inductor between one end and another end of the first inductor and an intermediate portion of the second inductor between one end and another end of the second inductor.

### CROSS REFERENCE TO RELATED APPLICATIONS

This application claims the benefit of priority to Japanese Patent Application No. 2016-225254 filed on Nov. 18, 2016 and is a Continuation Application of PCT Application No. PCT/JP2017/035906 filed on Oct. 3, 2017. The entire contents of each of these applications are hereby incorporated herein by reference.

### BACKGROUND OF THE INVENTION

### 1. Field of the Invention

The present invention relates to an LC filter.

### 2. Description of the Related Art

An LC filter including an LC resonator has been known. For example, WO 2007/119356 discloses a multilayer band pass filter in which a plurality of LC parallel resonators are arranged in parallel inside a multilayer body in which a plurality of dielectric layers are laminated.

An LC parallel resonator included in a multilayer band pass filter (band pass filter) disclosed in International Publication No. WO 2007/119356 includes a loop-shaped inductor formed so as to be wound around a winding axis by a line conductor pattern along a direction perpendicular to a lamination direction of a plurality of dielectric layers and two via conductor patterns extending in a lamination direction from the line conductor pattern. Magnetic coupling is generated between inductors included in two adjacent LC parallel resonators. The magnetic coupling is coupling through a magnetic flux, in which a magnetic flux between the inductors changes in accordance with changes in a current flowing in one of the inductors, and an induced electromotive force is generated in another inductor. Strong magnetic coupling facilitates signal transmission between the inductors, which widens a band of the band pass filter and consequently reduces an insertion loss.

The magnetic coupling generated between the inductors increases in a case in which in plan view from a winding axis direction of the inductor (1) regions surrounded by the respective two inductors (hereinafter, also referred to as air-core portions) overlap with each other, and (2) directions of the respective two inductors are the same. A direction of an inductor means a winding direction of the inductor with a connection node between one end of the inductor included in an LC resonator and a capacitor being a starting point.

In order to increase the magnetic coupling between the inductors, it is sufficient to provide an arrangement satisfying the conditions (1) and (2). However, there is a case in which one or both of the conditions (1) and (2) are intentionally not satisfied due to characteristics required for the LC filter, or a case in which it is not possible to satisfy one or both of the conditions (1) and (2) due to design constraints of the LC filter. For example, in the multilayer band pass filter disclosed in International Publication No. WO 2007/119356, in order to increase an attenuation amount at an attenuation pole, the directions of the respective inductors included in the two adjacent LC parallel resonators are opposite to each other so that the magnetic coupling between the inductors is intentionally weakened.

Weak magnetic coupling between the inductors suppresses the signal transmission between the inductors, and the insertion loss of the LC filter may be increased.

### SUMMARY OF THE INVENTION

Preferred embodiments of the present invention provide LC filters each having reduced insertion loss.

An LC filter according to a preferred embodiment of the present invention includes first and second LC resonators. The first and second LC resonators include first and second inductors, respectively. In plan view from a winding axis direction of the first inductor, an air-core portion of the first inductor does not coincide with an air-core portion of the second inductor. The LC filter further includes a bypass conductor. The bypass conductor connects an intermediate portion of the first inductor between one end and another end of the first inductor and an intermediate portion of the second inductor between one end and another end of the second inductor.

An LC filter according to a preferred embodiment of the present invention includes first and second LC resonators. The first LC resonator includes a first inductor and a first capacitor connected to one end of the first inductor at a first node. The second LC resonator includes a second inductor and a second capacitor connected to one end of the second inductor at a second node. In plan view from a winding axis direction of the first inductor, a winding direction of the first inductor with the first node being a starting point is opposite to a winding direction of the second inductor with the second node being a starting point. The LC filter further includes a bypass conductor. The bypass conductor connects an intermediate portion of the first inductor between one end and another end of the first inductor, and an intermediate portion of the second inductor between one end and another end of the second inductor.

With LC filters according to preferred embodiments of the present invention, signal transmission by magnetic coupling is compensated for by a bypass conductor coupling a first inductor and a second inductor. As a result, it is possible to reduce insertion loss of the LC filters.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a circuit diagram of a band pass filter that is an example of an LC filter according to a Preferred Embodiment 1 of the present invention.

FIG. 2 is an external perspective view of the band pass filter in FIG. 1.

FIG. 3 is an exploded perspective view illustrating an example of a multilayer structure of the band pass filter in FIG. 1.

FIG. 4 is a diagram illustrating conductor patterns of two inductors in the multilayer structure illustrated in FIG. 3.

FIG. 5 is a diagram of the conductor patterns illustrated in FIG. 4 in plan view from a Y axis direction.

FIG. 6 is a diagram illustrating conductor patterns of two inductors connected by a bypass conductor in the multilayer structure illustrated in FIG. 3.

FIG. 7 is a diagram of the conductor patterns illustrated in FIG. 6 in plan view from the Y axis direction.

FIG. 8 is a diagram illustrating a simulation result of an attenuation characteristic of the band pass filter according to the Preferred Embodiment 1 of the present invention.

FIG. 9 is a diagram of conductor patterns of two inductors connected by a bypass conductor according to a Preferred Embodiment 2 of the present invention in plan view from the Y axis direction.

FIG. 10 is a diagram illustrating a simulation result of an attenuation characteristic of a band pass filter according to the Preferred Embodiment 2 with a simulation result of the attenuation characteristic of the band pass filter according to the Preferred Embodiment 1 of the present invention.

FIG. 11 is a diagram illustrating simulation results of respective attenuation characteristics in cases in which a distance between a line conductor pattern included in a bypass conductor and a line conductor pattern included in inductors connected by the bypass conductor is changed in three stages.

### DETAILED DESCRIPTION OF THE PREFERRED EMBODIMENTS

Hereinafter, preferred embodiments of the present invention will be described in detail with reference to the accompanying drawings. Note that, in the drawings, the same or corresponding portions are denoted by the same reference numerals, and the description thereof will not be repeated.

### Preferred Embodiment 1

FIG. 1 is a circuit diagram of a band pass filter 1 that is an example of an LC filter according to a Preferred Embodiment 1 of the present invention. As illustrated in FIG. 1, the band pass filter 1 includes input/output terminals P1, P2, LC parallel resonators LC1 to LC4, capacitors C12, C34, and C14, and a bypass conductor BP1.

The LC parallel resonators LC1 to LC4 are disposed between the input/output terminals P1 and P2 in this order. The LC parallel resonators LC1 and LC2 are adjacent to each other, the LC parallel resonators LC2 and LC3 are adjacent to each other, and the LC parallel resonators LC3 and LC4 are adjacent to each other.

The LC parallel resonator LC1 includes an inductor L1 and a capacitor C1. The LC parallel resonator LC2 includes an inductor L2 and a capacitor C2. The LC parallel resonator LC3 includes an inductor L3 and a capacitor C3. The LC parallel resonator LC4 includes an inductor L4 and a capacitor C4.

One end of each of the inductor L1 and the capacitor C1 is connected to the input/output terminal P1. Another end of each of the inductor L1 and the capacitor C1 is grounded.

One end of the capacitor C12 is connected to the one end of each of the inductor L1 and the capacitor C1. Another end of the capacitor C12 is connected to one end of each of the inductor L2 and the capacitor C2. Another end of each of the inductor L2 and the capacitor C2 is grounded. Magnetic coupling M12 is generated between the inductors L1 and L2.

One end of each of the inductor L3 and the capacitor C3 is connected to one end of the capacitor C34. Another end of each of the inductor L3 and the capacitor C3 is grounded. The inductor L3 does not include a portion shared with the inductor L2, and is an inductor other than the inductor L2. Magnetic coupling M23 is generated between the inductors L2 and L3.

The bypass conductor BP1 connects a node MP2 located at an intermediate portion of the inductor L2 between the one end and the other end of the inductor L2, and a node MP3 located at an intermediate portion of the inductor L3 between the one end and the other end of the inductor L3. The intermediate portion of the inductor L2 does not include the one end or the other end of the inductor L2. Similarly, the intermediate portion of the inductor L3 does not include the one end or the other end of the inductor L3.

Another end of the capacitor C34 is connected to one end of each of the inductor L4 and the capacitor C4. The one end of each of the inductor L4 and the capacitor C4 is connected to the input/output terminal P2. Another end of each of the inductor L4 and the capacitor C4 is grounded. Magnetic coupling M34 is generated between the inductors L3 and L4.

One end of the capacitor C14 is connected to the input/output terminal P1. Another end of the capacitor C14 is connected to the input/output terminal P2.

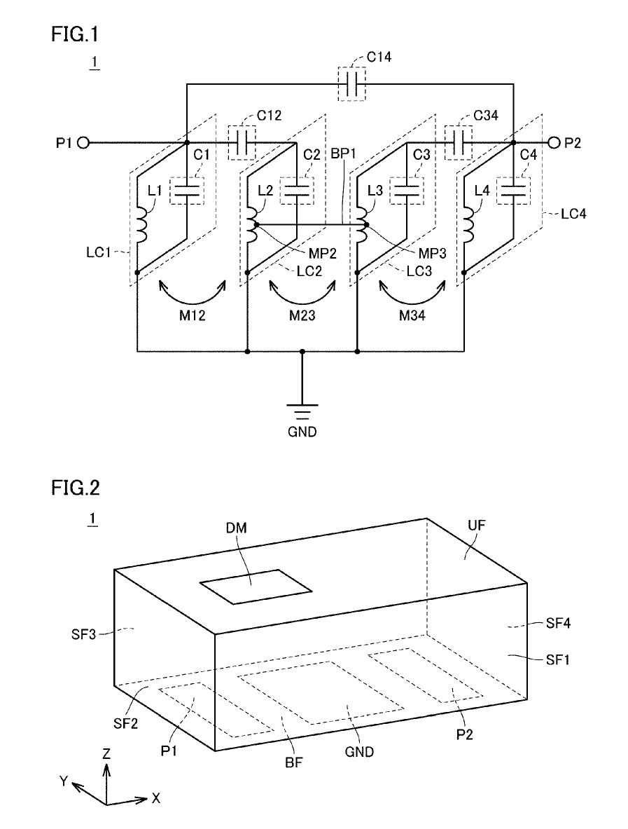

Hereinafter, a case in which the band pass filter 1 is configured as a multilayer body including a plurality of dielectrics will be described. FIG. 2 is an external perspective view of the band pass filter 1 in FIG. 1. As illustrated in FIG. 2, a lamination direction (height direction of the band pass filter 1) is defined as a Z axis direction. A long side (width) direction of the band pass filter 1 is defined as an X axis direction. A short side (depth) direction of the band pass filter 1 is defined as a Y axis direction. The X axis, the Y axis, and the Z axis are perpendicular or substantially perpendicular to each other.

The band pass filter 1 preferably has, for example, a rectangular or substantially rectangular parallelepiped shape. Respective surfaces of the band pass filter 1 along a direction perpendicular or substantially perpendicular to the lamination direction are defined as a bottom surface BF and an upper surface UF. Among surfaces along a direction parallel or substantially parallel to the lamination direction, respective surfaces along a ZX plane are defined as side surfaces SF1 and SF3. Among surfaces along the lamination direction, respective surfaces along a YZ plane are defined as side surfaces SF2 and SF4.

On the bottom surface BF, the input/output terminals P1, P2 and a ground electrode GND are provided. The input/output terminals P1, P2 and the ground electrode GND are preferably, for example, LGA (Land Grid Array) terminals in which planar electrodes are regularly arranged on the bottom surface BF.

A direction identification mark DM is provided on the upper surface UF. The direction identification mark DM is used to identify a direction of the band pass filter 1 when mounted.

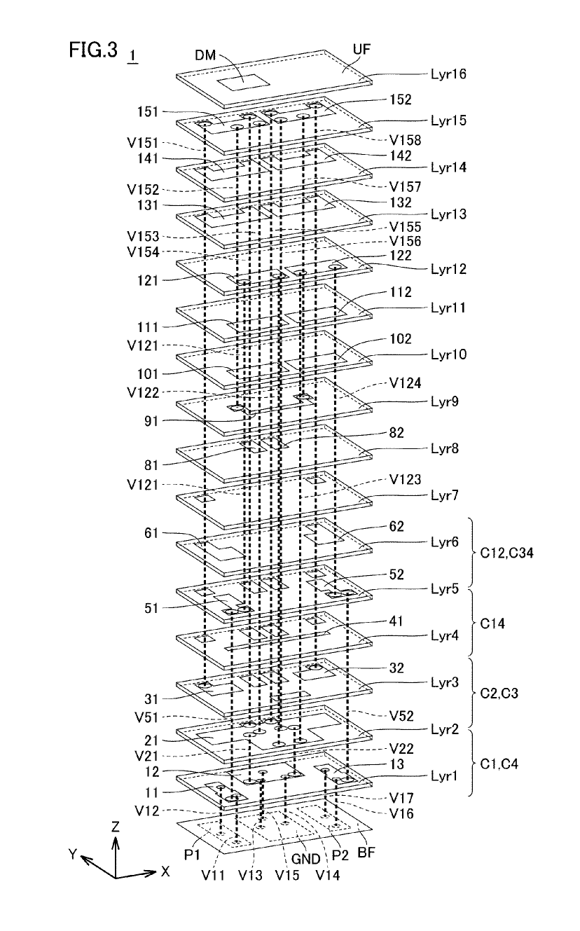

FIG. 3 is an exploded perspective view illustrating an example of a multilayer structure of the band pass filter 1 in FIG. 1. As illustrated in FIG. 3, the band pass filter 1 is a multilayer body in which a plurality of dielectric layers Lyr1 to Lyr16 are laminated in the Z axis direction. With the dielectric layer Lyr1 on a bottom surface BF side and the dielectric layer Lyr16 on an upper surface UF side, the dielectric layers Lyr1 to Lyr16 are laminated in the Z axis direction in this order. In FIG. 3, in order to make the connection relationship among the dielectric layers easy to see, a columnar via conductor pattern is drawn with a dotted line.

On the bottom surface BF of the dielectric layer Lyr1, the input/output terminals P1, P2 and the ground electrode GND are provided as described above. Further, capacitor conductor patterns 11, 13 and a ground conductor pattern 12 are provided on the dielectric layer Lyr1. The capacitor conductor pattern 11 and the input/output terminal P1 are connected to each other by each of via conductor patterns V11 and V12. The ground conductor pattern 12 and the ground electrode GND are connected to each other by each of via conductor patterns V13 to V15. The capacitor conductor pattern 13 and the input/output terminal P2 are connected to each other by each of via conductor patterns V16 and V17.

A ground conductor pattern 21 is provided on the dielectric layer Lyr2. The ground conductor pattern 21 and the ground conductor pattern 12 are connected to each other by each of via conductor patterns V21 and V22. The capacitor conductor pattern 11 and the ground conductor pattern 21 define the capacitor C1. The capacitor conductor pattern 13 and the ground conductor pattern 21 define the capacitor C4.

Capacitor conductor patterns 31 and 32 are provided on the dielectric layer Lyr3. The capacitor conductor pattern 31 and the ground conductor pattern 21 define the capacitor C2. The capacitor conductor pattern 32 and the ground conductor pattern 21 define the capacitor C3.

A capacitor conductor pattern 41 is provided on the dielectric layer Lyr4. Capacitor conductor patterns 51 and 52 are provided on the dielectric layer Lyr5. The capacitor conductor pattern 51 and the capacitor conductor pattern 11 are connected to each other by a via conductor pattern V51. The capacitor conductor patterns 52 and 13 are connected to each other by a via conductor pattern V52. The capacitor conductor patterns 41, 51, and 52 define the capacitor C14.

Capacitor conductor patterns 61 and 62 are provided on the dielectric layer Lyr6. The capacitor conductor pattern 61 and the capacitor conductor pattern 31 are connected to each other by a via conductor pattern V151. The capacitor conductor pattern 62 and the capacitor conductor pattern 32 are connected to each other by a via conductor pattern V158. The capacitor conductor patterns 61 and 51 define the capacitor C12. The capacitor conductor patterns 62 and 52 define the capacitor C34.

A line conductor pattern 91 is provided on the dielectric layer Lyr9. The line conductor pattern 91 connects via conductor patterns V152 and V157. The line conductor pattern 91 and the via conductor patterns V152 and V157 define the bypass conductor BP1.

Line conductor patterns 101 and 102 are provided on the dielectric layer Lyr10. The line conductor pattern 101 and the capacitor conductor pattern 51 are connected to each other by a via conductor pattern V121. The line conductor pattern 101 and the ground conductor pattern 21 are connected to each other by a via conductor pattern V122. The line conductor pattern 102 and the ground conductor pattern 21 are connected to each other by a via conductor pattern V123. The line conductor pattern 102 and the capacitor conductor pattern 52 are connected to each other by a via conductor pattern V124.

Line conductor patterns 111 and 112 are provided on the dielectric layer Lyr11. The line conductor pattern 111 and the line conductor pattern 101 are connected to each other by each of the via conductor patterns V121 and V122. The line conductor pattern 112 and the line conductor pattern 102 are connected to each other by each of the via conductor patterns V123 and V124.

Line conductor patterns 121 and 122 are provided on the dielectric layer Lyr12. The line conductor patterns 121 and 111 are connected to each other by each of the via conductor patterns V121 and V122. The line conductor patterns 122 and 112 are connected to each other by each of the via conductor patterns V123 and V124.

Line conductor patterns 131 and 132 are provided on the dielectric layer Lyr13. The line conductor pattern 131 and the capacitor conductor pattern 61 are connected to each other by the via conductor pattern V151. The line conductor pattern 131 and the line conductor pattern 91 are connected to each other by the via conductor pattern V152. The line conductor pattern 131 and the ground conductor pattern 21 are connected to each other by via conductor patterns V153 and V154. The line conductor pattern 132 and the ground conductor pattern 21 are connected to each other by via conductor patterns V155 and V156. The line conductor pattern 132 and the line conductor pattern 91 are connected to each other by the via conductor pattern V157. The line conductor pattern 132 and the capacitor conductor pattern 62 are connected to each other by the via conductor pattern V158.

Line conductor patterns 141 and 142 are provided on the dielectric layer Lyr14. The line conductor patterns 141 and 131 are connected to each other by each of the via conductor patterns V151 to V154. The line conductor patterns 142 and 132 are connected to each other by each of the via conductor patterns V155 to V158.

Line conductor patterns 151 and 152 are provided on the dielectric layer Lyr15. The line conductor patterns 151 and 141 are connected to each other by each of the via conductor patterns V151 to V154. The line conductor patterns 152 and 142 are connected to each other by each of the via conductor patterns V155 to V158.

As described above, the direction identification mark DM is provided on the upper surface UF of the dielectric layer Lyr16.

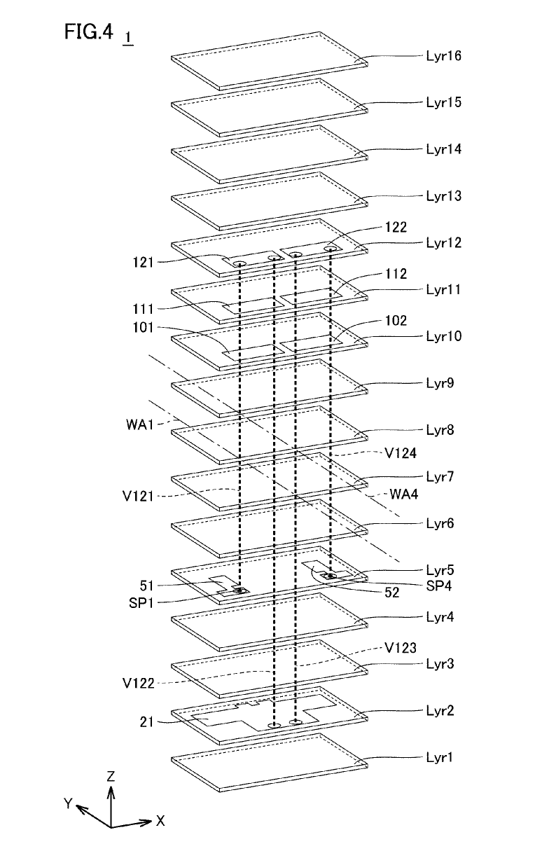

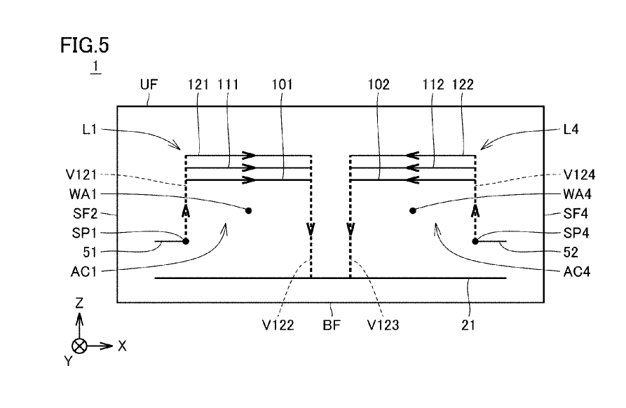

Hereinafter, a description will be provided of how the inductors L1 to L4 are provided in the multilayer structure of the band pass filter 1 illustrated in FIG. 3, with reference to FIG. 4 to FIG. 7. FIG. 4 is a diagram illustrating conductor patterns relating to the inductors L1 and L4 in the multilayer structure illustrated in FIG. 3. FIG. 5 is a diagram of the conductor patterns illustrated in FIG. 4 in plan view from the Y axis direction.

As illustrated in FIG. 4 and FIG. 5, the inductor L1 includes the via conductor pattern V121, the line conductor patterns 101, 111, 121, and the via conductor pattern V122. The inductor L1 is wound in a winding direction in which the via conductor pattern V121, the line conductor pattern 121 (101, 111) and the via conductor pattern V122 are followed in this order around a winding axis WA1 along the Y axis, with a connection node SP1 connecting the via conductor pattern V121 and the capacitor conductor pattern 51 being a starting point. The via conductor pattern V121, the line conductor pattern 121 (101, 111), and the via conductor pattern V122 define an air-core portion AC1.

The inductor L4 includes the via conductor pattern V124, the line conductor patterns 102, 112, 122, and the via conductor pattern V123. The inductor L4 is wound in a winding direction in which the via conductor pattern V124, the line conductor pattern 122 (102, 112), and the via conductor pattern V123 are followed in this order around a winding axis WA4 along the Y axis, with a connection node SP4 connecting the via conductor pattern V124 and the capacitor conductor pattern 52 being a starting point. The via conductor pattern V124, the line conductor pattern 122 (102, 112), and the via conductor pattern V123 define an air-core portion AC4.

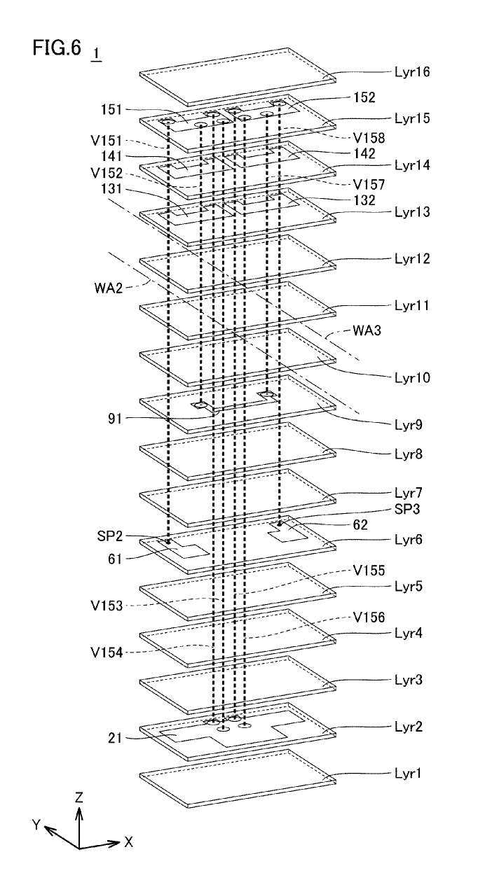

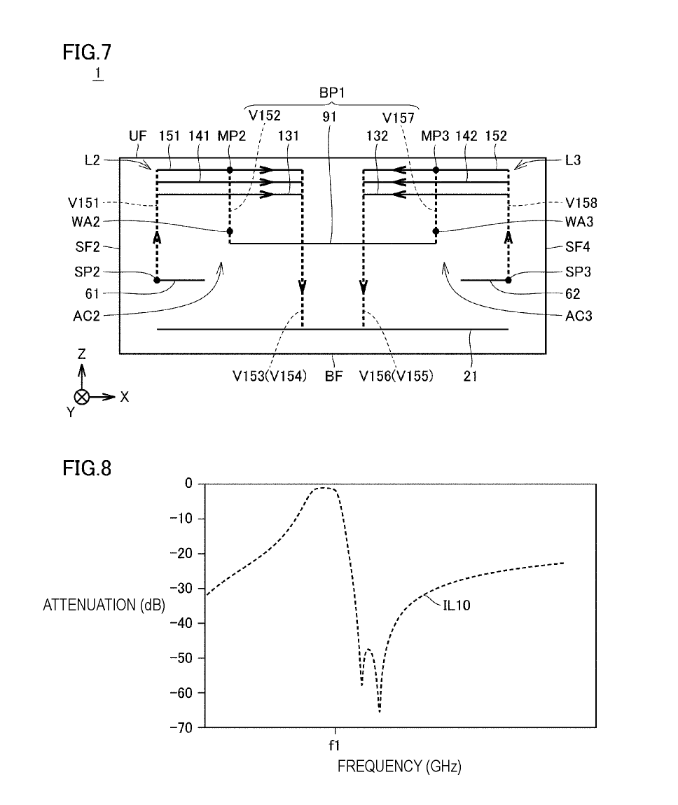

FIG. 6 is a diagram illustrating conductor patterns of the inductors L2 and L3 connected by the bypass conductor BP1 in the multilayer structure illustrated in FIG. 3. FIG. 7 is a diagram of the conductor patterns illustrated in FIG. 6 in plan view from the Y axis direction.

As illustrated in FIG. 6 and FIG. 7, the inductor L2 includes the via conductor pattern V151, the line conductor patterns 131, 141, 151, and the via conductor patterns V153 and V154. The inductor L2 is wound in a winding direction in which the via conductor pattern V151, the line conductor pattern 151 (131, 141), and the via conductor pattern V153 (V154) are followed in this order around a winding axis WA2 along the Y axis, with a connection node SP2 connecting the via conductor pattern V151 and the capacitor conductor pattern 61 being a starting point. The via conductor pattern V151, the line conductor pattern 151 (131, 141), and the via conductor pattern V153 (V154) define an air-core portion AC2.

The inductor L3 includes the via conductor pattern V158, the line conductor patterns 132, 142, 152, and the via conductor patterns V155 and V156. The inductor L3 does not include components (the via conductor pattern V151, the line conductor patterns 131, 141, 151, the via conductor patterns V153 and V154) of the inductor L2, and is an inductor other than the inductor L2 as described above. The inductor L3 is wound in a winding direction in which the via conductor pattern V158, the line conductor pattern 152 (132, 142), and the via conductor pattern V156 are followed in this order around a winding axis WA3 along the Y axis, with a connection node SP3 connecting the via conductor pattern V158 and the capacitor conductor pattern 62 being a starting point. The via conductor pattern V158, the line conductor pattern 152 (132, 142), and the via conductor pattern V156 define an air-core portion AC3.

Referring to FIG. 5 and FIG. 7, in plan view from the Y axis direction, a portion of the air-core portion AC1 of the inductor L1 and a portion of the air-core portion AC2 of the inductor L2 overlap with each other, and the winding direction of the inductor L1 and the winding direction of the inductor L2 are the same. Similarly, a portion of the air-core portion AC3 of the inductor L3 and a portion of the air-core portion AC4 of the inductor L4 overlap with each other, and the winding direction of the inductor L3 and the winding direction of the inductor L4 are the same.

On the other hand, as illustrated in FIG. 7, in plan view from the Y axis direction, the air-core portions AC2 and AC3 of the respective inductors L2 and L3 do not coincide with each other, and one of the air-core portions does not overlap with the other of the air-core portions. Thus, the magnetic coupling M23 generated between the inductors L2 and L3 is weaker than the magnetic coupling M12 generated between the inductors L1 and L2 and the magnetic coupling M34 generated between the inductors L3 and L4. As a result, the magnetic coupling M23 may act as a bottleneck in signal transmission between the input/output terminals P1 and P2, resulting in a large insertion loss.

Thus, in the Preferred Embodiment 1, as illustrated in FIG. 7, the node MP2 located at the intermediate portion of the inductor L2 between the one end and the other end of the inductor L2 and the node MP3 located at the intermediate portion of the inductor L3 between the one end of and the other end of the inductor L3 are connected by the bypass conductor BP1 (the via conductor pattern V152, the line conductor pattern 91, and the via conductor pattern V157). By directly connecting the inductors L2 and L3 to each other by the bypass conductor BP1 in this manner, the signal transmission by the magnetic coupling is compensated by signal transmission performed via the bypass conductor BP1, and a pass band of the band pass filter 1 is widened. As a result, it is possible to reduce an insertion loss of the band pass filter 1.

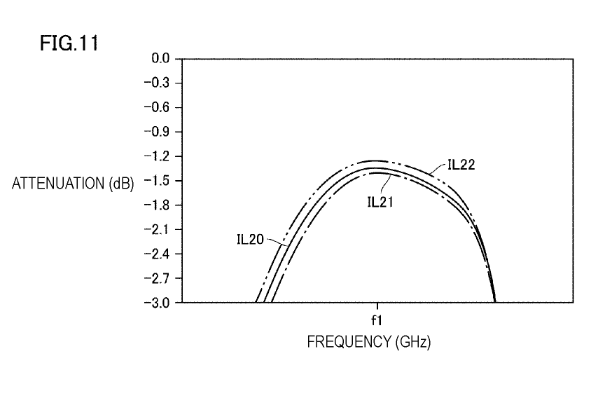

FIG. 8 is a diagram illustrating a simulation result of an attenuation characteristic IL10 of the band pass filter 1 according to the Preferred Embodiment 1. In FIG. 8, attenuation (dB) in a vertical axis is indicated as negative values. As an absolute value of attenuation is increased, an insertion loss is increased. This is also the same in FIG. 10 and FIG. 11. As illustrated in FIG. 8, the insertion loss of the band pass filter 1 is minimized in a frequency band including a frequency f1, and accordingly a wide pass band is achieved.

As described above, according to the LC filter of the Preferred Embodiment 1, signal transmission by magnetic coupling between two inductors is compensated by a bypass conductor coupling the two inductors. As a result, it is possible to reduce an insertion loss of the LC filter.

### Preferred Embodiment 2

In the Preferred Embodiment 1, as can be seen from FIG. 5 and FIG. 7, the bypass conductor BP1 overlaps with the respective air-core portions AC1 to AC4 of the inductors L1 to L4. Thus, a magnetic flux generated in each of the air-core portions AC1 to AC4 is impeded by the bypass conductor BP1, and an eddy current is generated in the bypass conductor BP1. As a result, heat (eddy current loss) is generated in the bypass conductor BP1, and thus an effect of reducing an insertion loss using the bypass conductor BP1 may be smaller than expected.

Thus, in a Preferred Embodiment 2 of the present invention, a bypass conductor does not overlap with an air-core portion of an inductor included in an LC filter. By arranging the bypass conductor in this manner, generation of an eddy current in the bypass conductor is able to be reduced or prevented, and an insertion loss is able to be further reduced as compared to the Preferred Embodiment 1.

A difference between the Preferred Embodiment 2 and the Preferred Embodiment 1 relates to an arrangement of the bypass conductor. Since the remaining configurations are the same or substantially the same, the description thereof will not be repeated.

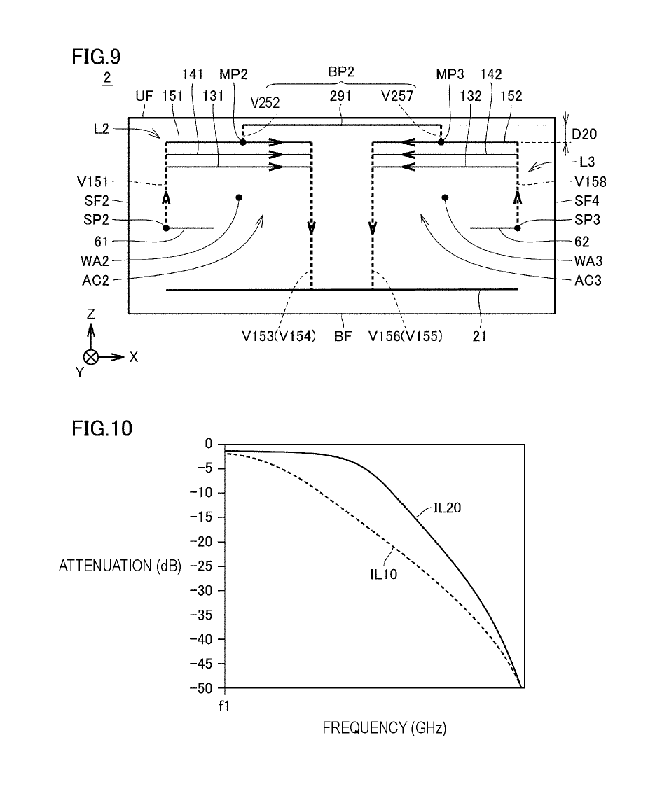

FIG. 9 is a diagram of conductor patterns of the inductors L2 and L3 connected by a bypass conductor BP2 in the Preferred Embodiment 2 in plan view from the Y axis direction. As illustrated in FIG. 9, in the Preferred Embodiment 2, the bypass conductor BP2 includes a line conductor pattern 291 and via conductor patterns V252 and V257, instead of the line conductor pattern 91 and the via conductor patterns V152 and V157 included in the bypass conductor BP1 in the Preferred Embodiment 1. The line conductor pattern 291 is disposed between the line conductor patterns 151, 152 and the upper surface UF. The via conductor patterns V252 and V257 extend from the line conductor patterns 151 and 152 toward the upper surface UF, respectively.

The air-core portions AC1 to AC4 of the respective inductors L1 to L4 are disposed between the line conductor patterns 151,152 and the bottom surface BF. On the other hand, the line conductor pattern 291 and the via conductor patterns V252 and V257 included in the bypass conductor BP2 are all disposed between the line conductor patterns 151, 152 and the upper surface UF. Accordingly, the bypass conductor BP2 does not overlap with any of the air-core portions AC1 to AC4.

FIG. 10 is a diagram illustrating a simulation result of an attenuation characteristic IL20 of a band pass filter 2 according to the Preferred Embodiment 2 with the simulation result of the attenuation characteristic IL10 of the band pass filter 1 according to the Preferred Embodiment 1. In a frequency band illustrated in FIG. 10, an insertion loss of the band pass filter 2 is smaller than the insertion loss of the band pass filter 1.

Referring again to FIG. 9, by increasing a distance D20 between the line conductor pattern 291 included in the bypass conductor BP2 and the line conductor pattern 152 included in the inductor L2 (or the line conductor pattern 151 included in the inductor L1), a distance between the line conductor pattern 291 and each of the air-core portions AC1 to AC4 is increased. Thus, a degree of a magnetic flux generated in the air-core portions AC1 to AC4 being impeded by the bypass conductor BP2 is reduced, and an eddy current generated in the bypass conductor BP2 is further reduced. As a result, it is possible to further reduce the insertion loss of the band pass filter 2.

FIG. 11 is a diagram illustrating simulation results of respective attenuation characteristics IL20 to IL22 in cases in which the distance D20 between the line conductor pattern 291 included in the bypass conductor BP2 and the line conductor pattern 152 included in the inductor L2 is changed in three stages. The respective distances D20 of the attenuation characteristics IL21, IL20, and IL22 ascend in this order. As illustrated in FIG. 11, the insertion loss decreases as the distance D20 increases around the frequency f1.

As described above, in the LC filter according to the Preferred Embodiment 2, similarly to the Preferred Embodiment 1, signal transmission by magnetic coupling between two inductors is compensated by a bypass conductor coupling the two inductors. As a result, it is possible to reduce an insertion loss of the LC filter.

Further, in the Preferred Embodiment 2, since the bypass conductor does not overlap with the air-core portion of the inductor included in the LC filter, it is possible to further reduce the insertion loss of the LC filter as compared to the Preferred Embodiment 1.

It is also expected that each of the preferred embodiments disclosed herein may be used in combination within a range consistent with the scope of the present invention. It should be understood that the preferred embodiments disclosed herein are illustrative and non-restrictive in every respect. It is intended that the scope of the present invention be indicated by the claims rather than the foregoing description, and that all changes within the meaning and range of equivalency of the claims shall be included therein.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An LC filter, comprising:
a first LC resonator including a first inductor;
a second LC resonator including a second inductor; and
a bypass conductor connecting an intermediate portion of the first inductor between one end and another end of the first inductor and an intermediate portion of the second inductor between one end and another end of the second inductor; wherein
in plan view from a winding axis direction of the first inductor, an air-core portion of the first inductor does not coincide with an air-core portion of the second inductor.

2. The LC filter according to the claim 1, wherein, in plan view from the winding axis direction of the first inductor, the air-core portion of the first inductor does not overlap with the air-core portion of the second inductor.

3. An LC filter, comprising:
a first LC resonator including a first inductor and a first capacitor connected to one end of the first inductor at a first node;
a second LC resonator including a second inductor and a second capacitor connected to one end of the second inductor at a second node; and
a bypass conductor connecting an intermediate portion of the first inductor between the one end and another end of the first inductor and an intermediate portion of the second inductor between the one end and another end of the second inductor;
wherein in plan view from a winding axis direction of the first inductor, a winding direction of the first inductor with the first node being a starting point is opposite to a winding direction of the second inductor with the second node being a starting point.

4. The LC filter according to claim 1, wherein the bypass conductor does not overlap with the air-core portion of the first inductor in plan view from the winding axis direction of the first inductor, and does not overlap with the air-core portion of the second inductor in plan view from a winding axis direction of the second inductor.

5. The LC filter according to claim 4, wherein
the LC filter is a multilayer filter including a plurality of dielectric layers laminated in a lamination direction;
the first inductor includes:
a first line conductor pattern extending along a first direction perpendicular or substantially perpendicular to the lamination direction; and
first and second via conductor patterns extending from the first line conductor pattern in a second direction along the lamination direction;
the second inductor includes:
a second line conductor pattern extending along the first direction; and
third and fourth via conductor patterns extending from the second line conductor pattern in the second direction; and
the bypass conductor includes:
a fifth via conductor pattern extending from the first line conductor pattern in a third direction opposite to the second direction;
a sixth via conductor pattern extending from the second line conductor pattern in the third direction; and
a third line conductor pattern connecting the fifth via conductor pattern and the sixth via conductor pattern.

6. The LC filter according to claim 2, wherein the bypass conductor does not overlap with the air-core portion of the first inductor in plan view from the winding axis direction of the first inductor, and does not overlap with the air-core portion of the second inductor in plan view from a winding axis direction of the second inductor.

7. The LC filter according to claim 6, wherein
the LC filter is a multilayer filter including a plurality of dielectric layers laminated in a lamination direction;
the first inductor includes:
a first line conductor pattern extending along a first direction perpendicular or substantially perpendicular to the lamination direction; and
first and second via conductor patterns extending from the first line conductor pattern in a second direction along the lamination direction;
the second inductor includes:
a second line conductor pattern extending along the first direction; and
third and fourth via conductor patterns extending from the second line conductor pattern in the second direction; and
the bypass conductor includes:
a fifth via conductor pattern extending from the first line conductor pattern in a third direction opposite to the second direction;
a sixth via conductor pattern extending from the second line conductor pattern in the third direction; and
a third line conductor pattern connecting the fifth via conductor pattern and the sixth via conductor pattern.

8. The LC filter according to claim 3, wherein the bypass conductor does not overlap with the air-core portion of the first inductor in plan view from the winding axis direction of the first inductor, and does not overlap with the air-core portion of the second inductor in plan view from a winding axis direction of the second inductor.

9. The LC filter according to claim 8, wherein
the LC filter is a multilayer filter including a plurality of dielectric layers laminated in a lamination direction;
the first inductor includes:
a first line conductor pattern extending along a first direction perpendicular or substantially perpendicular to the lamination direction; and
first and second via conductor patterns extending from the first line conductor pattern in a second direction along the lamination direction;
the second inductor includes:
a second line conductor pattern extending along the first direction; and
third and fourth via conductor patterns extending from the second line conductor pattern in the second direction; and
the bypass conductor includes:
a fifth via conductor pattern extending from the first line conductor pattern in a third direction opposite to the second direction;
a sixth via conductor pattern extending from the second line conductor pattern in the third direction; and
a third line conductor pattern connecting the fifth via conductor pattern and the sixth via conductor pattern.
